(19) United States
(12) Patent Application Publication
(10) Pub. No.: US 2016/0343571 A1
(43) Pub. Date: Nov. 24, 2016

(54) Method for removing dielectric layers from semiconductor components by using a laser beam

(71) Applicant: ROFIN-BAASEL LASERTECH GMBH & CO. KG, STARNBERG (DE)

(72) Inventors: ROLAND MAYERHOFER, ROETTENBACH (DE); RICHARD HENDEL, WEILHEIM (DE); WENJIE ZHU, STOCKDORF (DE)

(21) Appl. No.: 15/224,831

(22) Filed: Aug. 1, 2016

Related U.S. Application Data
(63) Continuation of application No. PCT/EP2014/077248, filed on Dec. 10, 2014.

(30) Foreign Application Priority Data
Jan. 31, 2014 (DE) 10 2014 101 235.6

(51) Int. Cl. H01L 21/268; H01L 31/18

(52) U.S. Cl. CPC H01L 21/268; H01L 31/18

(57) ABSTRACT

A method for removing dielectric layers from semiconductor components by way of a laser beam. The dielectric layer is irradiated with a laser beam which has, upon incidence on the dielectric layer, a substantially homogeneous power density over the laser beam cross-section.

### CROSS-REFERENCE TO RELATED APPLICATION

This application is a continuation, under 35 U.S.C. §120, of copending international application No. PCT/EP2014/077248, filed Dec. 10, 2014, which designated the United States; this application also claims the priority, under 35 U.S.C. §119, of German patent application No. DE 10 2014 101 235.6, filed Jan. 31, 2014; the prior applications are herewith incorporated by reference in their entirety.

### BACKGROUND OF THE INVENTION

### Field of the Invention

The invention relates to a method for removing dielectric layers from semiconductor components by means of a laser beam. For the production of solar cells it is necessary to remove dielectric layers from a semiconductor component, such as from a silicon wafer, for example. Hitherto, fundamental mode lasers have been used for this purpose, said lasers generating a laser beam having a Gaussian power density as viewed over its round cross section. This results in high power densities in the center of the laser beam and low power densities at the edge of the laser beam, which, upon incidence of the laser beam on the dielectric layer, leads to great thermal damage in the region of the center and inadequate removal at the edge of the laser beam or spot.

For removal with a low degree of damage, a wide variety of lasers can be used which typically generate laser light having pulse durations of nanoseconds to femtoseconds, repetition rates in the relatively high kHz range (100 to 1000 kHz), usually very good beam qualities (M²<2) and wavelengths in the visible or UV range. Said lasers produce tracks having widths in a range of 30 to 60 μm in which the dielectric layer is removed. In this case, a high repetition rate is crucial for a high processing speed and hence a high throughput. The lasers used hitherto can achieve typical scanning speeds of a maximum of 5 to 8 m/s with maximum repetition rates of up to 400 kHz.

Yet higher throughput and faster processing would be desirable in industrial applications.

### SUMMARY OF THE INVENTION

It is accordingly an object of the invention to provide a method for removing dielectric layers from a semiconductor component with a laser beam which overcomes the above-mentioned and other disadvantages of the heretofore-known devices and methods of this general type and which provides for faster processing and thus a higher throughput.

With the foregoing and other objects in view there is provided, in accordance with the invention, a method for removing a dielectric layer from a semiconductor component. The novel method comprises:

irradiating the dielectric layer with a laser beam having a substantially homogeneous power density as viewed over a cross section of the laser beam upon incidence on the dielectric layer.

In other words, the dielectric layer is irradiated with a laser beam which has a substantially homogeneous power density as viewed over its cross section upon incidence on the dielectric layer. The beam may be referred to as a top hat beam, due to the resemblance of its power profile to a top hat. The beam has a near-uniform or uniform energy density (fluence) across its entire spot, whether the spot is circular round or rectangular or square.

What is achieved as a result is that a laser beam having relatively high average power can be used, without incurring greater thermal damage to the semiconductor component than in the case of the hitherto used lasers having fundamental mode beam quality, and specifically the damage or inadequate removal in the marginal region as a result of a Gaussian profile is minimized or avoided. Consequently, the processing speed and hence a higher throughput can be achieved.

Other features which are considered as characteristic for the invention are set forth in the appended claims.

Although the invention is described herein as being embodied in a method for removing a dielectric layer from a semiconductor component by way of a laser beam, it is nevertheless not intended to be limited to the described details, since various modifications and changes may be made therein without departing from the spirit of the invention and within the scope and range of equivalents of the claims.

The method of operation of the invention, however, together with additional objects and advantages thereof will be best understood from the following description of specific embodiments of the invention.

### DETAILED DESCRIPTION OF THE INVENTION

In one preferred configuration of the invention, a laser beam is used whose power density has a top hat profile, that is to say a cylinder-shaped top hat-shaped beam profile. Such a laser beam thus has a homogeneous power density over the entire cross section upon incidence on the dielectric layer, that is to say in the processing plane. In this case, the cross section has a circular shape, but may preferably also have a rectangular, in particular square, shape. Preferably, the diameter in the case of a round cross section or the edge length in the case of a square cross section is in each case 200 μm.

The beam profile according to the invention can be generated in a simple manner by means of a step-index fiber by virtue of the laser beam being shaped by such a fiber. This is done by fiber coupling and not by external optical units such as diffractive or refractive optical elements.

In this case, a single-mode laser or fundamental mode laser can be used for generating the laser beam.

Preferably, however, the laser beam is generated by a multimode laser. By using the multimode laser, by means of an efficient coupling of the laser beam generated thereby into a step-index fiber, it is possible to generate a very homogeneous beam profile in the processing plane which is excellently suitable for the removal of dielectric layers and, by employing high average powers, enables significantly higher throughputs than with the previous fundamental mode lasers. Pulsed lasers having pulse durations in a range of 10-200 ns are used for the processing. The repetition rates are then in a range of 10-30 kHz.

For removing dielectric layers, formed for example by silicon nitride or silicon dioxide, from semiconductor components, such as from a silicon wafer, for instance, it is possible to use for example a laser beam having an average power of up to 100 W and a wavelength of 532 nm. Such a laser beam can be coupled into a round or square fiber having a diameter or edge length of 100 μm, such that a typical spot size of 200 μm is achieved. After the homogenization and conversion of the laser beam profile in the fiber, the end of the fiber is imaged as it were onto the workpiece. For this purpose, the beam is expanded downstream of the fiber with a focal length fcoll and then focused with ffoc onto the workpiece. The spot size then results computationally from (fiber diameter or edge length*fcoll)/ffoc.

In a preferred case, the fiber cross section of 100 μm then results in a 200 μm spot by virtue of a ratio of ffoc/fcoll of 2:1. A punctiform opening of the passivated rear side with such spots produces properties of the solar cell that are at least the same as, or better than, those in the case of a linear opening with fundamental mode lasers. With this type of processing, the area to be opened is in the range of 5-10%. The rear side of the solar cell is scanned linearly; in this case, the laser pulses may or may not overlap. The scanning speeds used when carrying out the method according to the invention, at 15 m/s, are already almost 100% higher than in the case of the fundamental mode laser.

1. A method for removing a dielectric layer from a semiconductor component, the method comprising:
irradiating the dielectric layer with a laser beam having a substantially homogeneous power density as viewed over a cross section of the laser beam upon incidence on the dielectric layer.

2. The method according to claim 1, which comprises employing a laser beam having a power density with a top hat profile.

3. The method according to claim 1, which comprises shaping the laser beam with a step-index fiber.

4. The method according to claim 3, which comprises generating the laser beam with a multimode laser.

5. The method according to claim 3, which comprises generating the laser beam with a fundamental mode laser.
